(19) United States
(12) Patent Application Publication
(10) Pub. No.: US 2017/0149005 A1
(43) Pub. Date: May 25, 2017

(54) SOLAR CELL INCLUDING LIGHT-ABSORBING LAYER CONTAINING PEROVSKITE TYPE COMPOUND

(71) Applicant: Panasonic Corporation, Osaka (JP)

(72) Inventors: MICHIO SUZUKA, Osaka (JP); NAOKI HAYASHI, Kyoto (JP); RYUUSUKE UCHIDA, Osaka (JP); AKIO MATSUSHITA, Kyoto (JP)

(21) Appl. No.: 15/352,686

(22) Filed: Nov. 16, 2016

(30) Foreign Application Priority Data
Nov. 24, 2015 (JP) 2015-228332

(51) Int. Cl. H01L 51/42; H01L 51/44

(52) U.S. Cl. CPC H01L 51/4213; H01L 51/448; H01L 51/441

(57) ABSTRACT

A solar cell according to one aspect of the present disclosure includes: a first electrode; an electron transport layer on the first electrode; a light-absorbing layer located on the electron transport layer and containing a perovskite type compound; a second electrode on the light-absorbing layer; and a sealing body sealing at least a part of the first electrode, the electron transport layer, the light-absorbing layer, and at least a part of the second electrode. A gas containing oxygen is present between the sealing body and each of the at least a part of the first electrode, the electron transport layer, the light-absorbing layer, and the at least a part of the second electrode. The concentration of the oxygen is 5% or more, and the concentration of water is 300 ppm or less on a volume fraction basis.

### BACKGROUND

1. Technical Field

The present disclosure relates to a solar cell.

2. Description of the Related Art

In recent years, research and development of solar cells has been carried out using as a light-absorbing material, a perovskite type compound represented by AMX₃ or a compound having a structure similar thereto. Japanese Unexamined Patent Application Publication No. 2014-175472 has disclosed a solar cell in which a first electrode layer, an electron transport layer, a light-absorbing layer formed of a perovskite type compound represented by (RNH₃)ₙPbI₍₂₊ₙ₎, a hole transport layer, and a second electrode layer are provided in this order on a substrate.

### SUMMARY

In one general aspect, the techniques disclosed here feature a solar cell comprising: a first electrode; an electron transport layer which is located on the first electrode and which contains a semiconductor; a light-absorbing layer which is located on the electron transport layer and which contains a perovskite type compound represented by a composition formula AMX₃, where A is a site for one or more monovalent cations, M is a site for one or more divalent cations, and X is a site for one or more halide anions; a second electrode which is located on the light-absorbing layer; and a sealing body which seals at least a part of the first electrode, the electron transport layer, the light-absorbing layer, and at least a part of the second electrode. Between the sealing body and each of the at least a part of the first electrode, the electron transport layer, the light-absorbing layer, and the at least a part of the second electrode, a gas containing oxygen is present. The concentration of the oxygen in the gas is 5% or more on a volume fraction basis, and the concentration of water in the gas is 300 ppm or less on a volume fraction basis.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a cross-sectional view of a solar cell according to a first embodiment of the present disclosure;

FIG. 2 is a cross-sectional view of a solar cell according to a second embodiment of the present disclosure;

FIG. 3 is a cross-sectional view of a solar cell according to a third embodiment of the present disclosure;

FIG. 4 is a cross-sectional view of a solar cell according to a fourth embodiment of the present disclosure;

FIG. 5 is a cross-sectional view of a solar cell according to a fifth embodiment of the present disclosure; and

FIG. 6 is a cross-sectional view of a solar cell according to a sixth embodiment of the present disclosure.

### DETAILED DESCRIPTION

Prior to the description of embodiments of the present disclosure, the knowledge obtained by the inventors of the present disclosure will be described. In a related solar cell using a perovskite type compound as a light-absorbing material, as the operation time thereof is increased, the conversion efficiency is decreased. As one factor of decreasing the conversion efficiency, decomposition of the perovskite type compound used as a light-absorbing material caused by moisture in the air may be mentioned. In addition, in the case in which a solar cell has a hole transport layer, when a hole transport material in the hole transport layer is partially oxidized, the hole transport performance can be improved. However, an oxidant of the hole transport material is reduced by moisture in the air. Hence, it is believed that the decrease in hole transport performance caused thereby is also partially responsible for the decrease in conversion efficiency.

On the other hand, by the structure according to one aspect of the present disclosure, a light-absorbing layer containing a perovskite type compound and a hole transport layer can be suppressed from being brought into contact with moisture in the air. Hence, a solar cell having excellent durability can be provided.

The present disclosure includes solar cells described in the following items.

### [Item 1]

A solar cell according to one aspect of the present disclosure comprises: a first electrode; an electron transport layer which is located on the first electrode and which contains a semiconductor; a light-absorbing layer which is located on the electron transport layer and which contains a perovskite type compound represented by a composition formula AMX₃, where A is a site for one or more monovalent cations, M is a site for one or more divalent cations, and X is a site for one or more halide anions; a second electrode which is located on the light-absorbing layer; and a sealing body which seals at least a part of the first electrode, the electron transport layer, the light-absorbing layer, and at least a part of the second electrode. Between the sealing body and each of the at least a part of the first electrode, the electron transport layer, the light-absorbing layer, and the at least a part of the second electrode, a gas containing oxygen is present. The concentration of the oxygen in the gas is 5% or more on a volume fraction basis, and the concentration of water in the gas is 300 ppm or less on a volume fraction basis.

### [Item 2]

A solar cell according to another aspect of the present disclosure comprises: a first electrode; an electron transport layer which is located on the first electrode and which contains a semiconductor; a light-absorbing layer which is located on the electron transport layer and which contains a perovskite type compound represented by a composition formula AMX₃, where A is a site for one or more monovalent cations, M is a site for one or more divalent cations, and X is a site for one or more halide anions; a second electrode which is located on the light-absorbing layer; a sealing body which seals at least a part of the first electrode, the electron transport layer, the light-absorbing layer, and at least a part of the second electrode; and a moisture absorber located between the sealing body and each of the at least a part of the first electrode, the electron transport layer, the light-absorbing layer, and the at least a part of the second electrode. Between the sealing body and each of the at least a part of the first electrode, the electron transport layer, the light-absorbing layer, and the at least a part of the second electrode, a gas containing oxygen is present. The concentration of the oxygen in the gas is 5% or more on a volume fraction basis.

### [Item 3]

In the solar cell described in Item 1 or 2, the gas may further contain an inert gas, and the concentration of the inert gas in the gas may be 50% or more on a volume fraction basis.

### [Item 4]

In the solar cell described in any one of Items 1 to 3, the concentration of water in the gas may be 130 ppm or less on a volume fraction basis.

### [Item 5]

In the solar cell described in any one of Items 1 to 4, the gas and the light-absorbing layer may be in contact with each other.

### [Item 6]

The solar cell described in any one of Items 1 to 5 may further comprise a hole transport layer disposed between the light-absorbing layer and the second electrode, and the sealing body may further seal the hole transport layer.

### [Item 7]

In the solar cell described in Item 6, the gas and the hole transport layer may be in contact with each other.

### [Item 8]

The solar cell described in any one of Items 1 to 7 may further comprise a porous layer disposed in the light-absorbing layer, the porous layer being in contact with the electron transport layer and containing a porous material.

### [Item 9]

In the solar cell described in any one of Items 1 to 8, the semiconductor may be titanium oxide.

### [Item 10]

In the solar cell described in any one of Items 1 to 9, the one or more monovalent cations may include at least one selected from the group consisting of a methylammonium cation and a formamidinium cation. [Item 11]

In the solar cell described in any one of Items 1 to 10, the one or more divalent cations may include at least one selected from the group consisting of Pb²⁺, Ge²⁺, and Sn²⁺,

### [Item 12]

The solar cell described in any one of Items 1 to 11 may further comprise a substrate supporting the first electrode.

Hereinafter, with reference to the drawings, the embodiments of the present disclosure will be described.

### First Embodiment

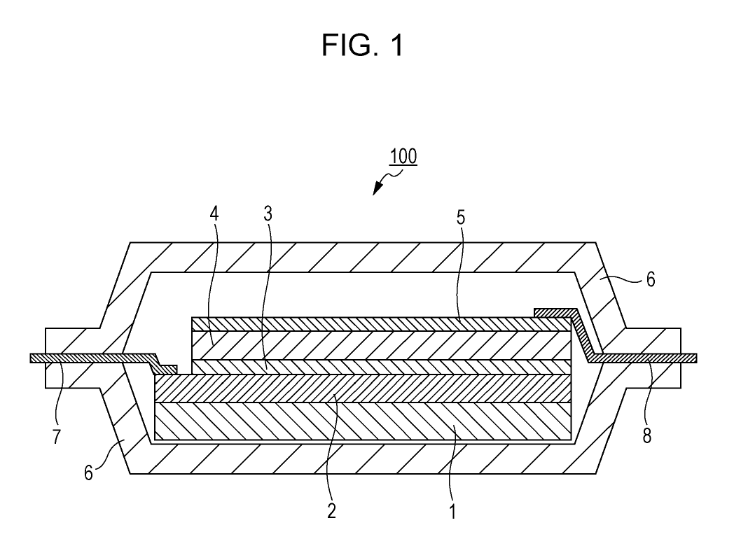

As shown in FIG. 1, a solar cell 100 according to this embodiment includes a first electrode 2, an electron transport layer 3, a light-absorbing layer 4, a second electrode 5, and a sealing body 6.

The electron transport layer 3 is located on the first electrode 2. The electron transport layer 3 contains a semiconductor. The light-absorbing layer 4 is disposed on the electron transport layer 3. The light-absorbing layer 4 contains a perovskite type compound represented by a composition formula AMX₃. In this composition formula, A is a site for one or more monovalent cations, M is a site for one or more divalent cations, and X is a site for one or more halide anions. The second electrode 5 is located on the light-absorbing layer 4. The sealing body 6 seals the first electrode 2, the electron transport layer 3, the light-absorbing layer 4, and the second electrode 5. The first electrode 2 and the second electrode 5 are each electrically connected to the outside of the sealing body 6.

Between the sealing body 6 and each of the first electrode 2, the electron transport layer 3, the light-absorbing layer 4, and the second electrode 5, a gas is present. This gas contains oxygen. The concentration of the oxygen in this gas is 5% or more on a volume fraction basis, and the concentration of water is 300 ppm or less on a volume fraction basis.

The solar cell 100 may further include a substrate 1. In this case, as shown in FIG. 1, the first electrode 2 is disposed on the substrate 1.

Next, fundamental operation and effect of the solar cell 100 of this embodiment will be described. When light is irradiated on the solar cell 100, the light-absorbing layer 4 absorbs the light, and hence, excited electrons and holes are generated. The excited electrons move to the electron transport layer 3. On the other hand, the holes generated in the light-absorbing layer 4 move to the second electrode 5. The electron transport layer 3 and the first electrode 2 are connected to each other, and the first electrode 2 and the second electrode 5 are each electrically connected to the outside of the sealing body 6. Hence, a current can be extracted from the solar cell 100 using the first electrode 2 and the second electrode 5 as a negative electrode and a positive electrode, respectively.

In addition, between the sealing body 6 and each of the first electrode 2, the electron transport layer 3, the light-absorbing layer 4, and the second electrode 5, a gas containing oxygen is present. The concentration of the oxygen in the gas is 5% or more on a volume fraction basis, and the concentration of water in this gas is 300 ppm or less on a volume fraction basis. Hence, the solar cell 100 has high durability. The reason for this can be explained as follows.

The energy level of the valence band of the perovskite type compound AMX₃ contained in the light-absorbing layer 4 is higher than the oxidation-reduction potential of water.

Hence, when water is present, in the perovskite type compound, the following oxidation reaction of water occurs, and oxygen, protons, and electrons are generated.

2H₂O→O₂+4H⁺+4e⁻ (1)

For example, when the perovskite type compound is CH₃NH₃PbI₃, by the protons and oxygen generated by the reaction represented by the formula (1), the following reactions occur.

CH₃NH₃PbI₃+H⁺→CH₃NH₃⁺+HPbI₃ (2)

CH₃NH₃PbI₃+½O₂→CH₃NH₃I+PbO+I₂ (3)

As a result of the reactions represented by the formulas (1) to (3), the perovskite type compound is decomposed, and the color thereof is turned into yellow or white. Hence, the light-absorbing performance of the light-absorbing layer 4 is degraded.

According to the formula (1) and Le Chatelier's principle, as the amount of water around the perovskite type compound is increased, or as the amount of oxygen is decreased, the reaction represented by the formula (1) is liable to occur. In the gas contained in a space sealed by the sealing body 6, 5% or more of oxygen is contained on a volume fraction basis, and the concentration of water is 300 ppm or less on a volume fraction basis. Hence, the probability of the occurrence of the reaction represented by the formula (1) in the solar cell 100 can be reduced. Accordingly, in the solar cell 100, the decomposition of the perovskite type compound contained in the light-absorbing layer 4 can be suppressed. Hence, since the decrease in conversion efficiency of the solar cell 100 with the time can be suppressed, the durability thereof can be improved.

Measurement of the water concentration and the oxygen concentration in the gas contained in the space sealed by the sealing body 6 can be performed, for example, by an atmospheric pressure ionization mass spectrometer (API-MS). First, the solar cell 100 is placed in a chamber filled with an inert gas, such as argon or krypton. After the sealing body 6 is broken in the chamber, the gas contained in the space sealed by the sealing body 6 is allowed to flow out of the solar cell 100. Subsequently, the gas in the chamber is quantitatively measured by API-MS. The quantitative analysis of every component in the gas contained in the space sealed by the sealing body 6 is performed, and the rate of water or oxygen to the total amount is calculated, so that the water concentration and the oxygen concentration can be obtained. As a gas other than oxygen and water contained in the space sealed by the sealing body 6, for example, inert gases, such as nitrogen and a rare gas, and carbon dioxide may be mentioned.

In addition, when the same type of inert gas as that filled in the chamber for the gas analysis is contained in the space sealed by the sealing body 6, an accurate gas analysis may be difficult to perform. Hence, when the type of gas contained in the space sealed by the sealing body 6 is not known, two solar cells equivalent to each other are prepared, and the gas analysis is performed on the two solar cells in accordance with the procedure described above using different types of inert gases from each other as the inert gas filled in the chamber. When the two analytical results are compared to each other, the composition of the gas contained in the space sealed by the sealing body 6 can be obtained.

The solar cell 100 of this embodiment can be formed, for example, by the following method. First, the first electrode 2 is formed on the surface of the substrate 1. Next, the electron transport layer 3 is formed on the first electrode 2 by a sputtering method or the like. In addition, the light-absorbing layer 4 is formed on the electron transport layer 3 by a coating method or the like. Subsequently, on the light-absorbing layer 4, the second electrode 5 is formed. Next, the first electrode 2 and the second electrode 5 are connected to a first wire 7 and a second wire 8, respectively. Finally, in the state in which a part of the first wire 7 and a part of the second wire 8 are extended outside, the sealing body 6 is formed so as to seal the substrate 1, the first electrode 2, the electron transport layer 3, the light-absorbing layer 4, and the second electrode 5. By the steps described above, the solar cell 100 can be obtained.

Hereinafter, the individual constituent elements of the solar cell 100 will be described in detail.

### <Substrate 1>

The substrate 1 functioning as an auxiliary constituent element supports the individual layers of the solar cell 100. As a material of the substrate 1, a transparent material, such as a glass substrate or a plastic substrate, may be used. As the plastic substrate, a plastic film may be used. In addition, when the first electrode 2 has a sufficient strength, since the individual layers can be supported by the first electrode 2, the substrate 1 may not be always required.

### <First Electrode 2>

The first electrode 2 has electric conductivity. In addition, the first electrode 2 has translucency. The first electrode 2 has, for example, characteristics of allowing visible light and near infrared light to pass therethrough. The first electrode 2 maybe formed, for example, from a material, such as a transparent metal oxide having electric conductivity. As the transparent metal oxide having electric conductivity, for example, there may be mentioned an indium-tin composite oxide, an antimony-doped tin oxide, a fluorine-doped tin oxide, a boron-doped, an aluminum-doped, a gallium-doped, or an indium-doped zinc oxide, or a composite of those mentioned above.

In addition, the first electrode 2 may also be formed using an opaque material by providing a pattern through which light is allowed to pass. As the pattern through which light is allowed to pass, for example, a pattern of straight lines (striped shape), wave lines, a lattice form (mesh form), or many fine through holes regularly or irregularly arranged may be mentioned, or alternatively, a metal layer having a pattern opposite to that described above, that is, a metal layer in which the region in which the pattern is formed and the region in which the pattern is not formed are reversed from each other, may also be mentioned. When a metal layer has the pattern as described above, light is allowed to pass through the portion at which the electrode material is not present. As an opaque electrode material, for example, there may be mentioned platinum, gold, silver, copper, aluminum, rhodium, indium, titanium, iron, nickel, tin, zinc, or an alloy containing at least one of the metals mentioned above. In addition, as the electrode material, a carbon material having electric conductivity may also be used.

The optical transmittance of the first electrode 2 is, for example, 50% or more. The optical transmittance of the first electrode 2 may also be 80% or more. The wavelength of light to be allowed to pass depends on an absorption wavelength of the light-absorbing layer 4. The thickness of the first electrode 2 is, for example, in a range of 1 to 1,000 nm.

### <Electron Transport Layer 3>

The electron transport layer 3 contains a semiconductor. The electron transport layer 3 may contain a semiconductor having a bandgap of 3.0 eV or more. Since the electron transport layer 3 is formed from a semiconductor having a bandgap of 3.0 eV or more, the electron transport layer 3 enables visible light and infrared light to pass to the light-absorbing layer 4. As an example of the semiconductor, an organic or an inorganic n-type semiconductor may be mentioned.

As the organic n-type semiconductor, an imide compound, a quinone compound, and a fullerene and derivatives thereof may be mentioned. In addition, as the inorganic semiconductor, for example, an oxide of a metal element or a perovskite oxide may be used. As the oxide of a metal element, for example, an oxide of Cd, Zn, In, Pb, Mo, W, Sb, Bi, Cu, Hg, Ti, Ag, Mn, Fe, V, Sn, Zr, Sr, Ga, or Cr may be mentioned. As a more particular example, TiO₂ may be mentioned. As an example of the perovskite oxide, SrTiO₃ or CaTiO₃ may be mentioned.

In addition, the electron transport layer 3 may be formed from a material having a bandgap of more than 6 eV. As the material having a bandgap of more than 6 eV, a halogenated material of an alkali metal or an alkaline earth metal, such as lithium fluoride or calcium fluoride, an alkali metal oxide such as magnesium oxide, or silicon dioxide may be mentioned. In this case, in order to secure the electron transport performance of the electron transport layer 3, the thickness thereof may be set to 10 nm or less.

The electron transport layer 3 may be formed by laminating the same material or by alternately laminating different materials.

### <Light-Absorbing Layer 4>

The light-absorbing layer 4 contains a compound having a perovskite structure represented by a composition formula AMX₃. A is a site for one or more monovalent cations. As an example of A, a monovalent cation, such as an alkali metal cation or an organic cation, may be mentioned. Furthermore, in particular, a methylammonium cation (CH₃NH₃⁺), a formamidinium cation (NH₂CHNH₂⁺), or a cesium cation (Cs⁺) may be mentioned. M is a site for one or more divalent cations. As an example of M, a divalent cation of a transition metal or one of Group XIII to XV elements may be mentioned. Furthermore, in particular, Pb²⁺, Ge²⁺, and Sn²⁺ may be mentioned. X is a site for one or more monovalent anions such as a halogen anion. The site of each of A, M, and X may be occupied by at least two types of ions. As a particular example of the compound having a perovskite structure, for example, there may be mentioned CH₃NH₃PbI₃, NH₂CHNH₂PbI₃, CH₃CH₂NH₃PbI₃, CH₃NH₃PbBr₃, CH₃NH₃PbCl₃, CsPbI₃, or CsPbBr₃.

The thickness of the light-absorbing layer 4 is, for example, in a range of 100 to 1,000 nm. The light-absorbing layer 4 may be formed by a solution coating method or a deposition method.

### <Second Electrode 5>

The second electrode 5 has electric conductivity. In addition, the second electrode 5 is not in ohmic contact with the light-absorbing layer 4. Furthermore, the second electrode 5 has a blocking property against electrons from the light-absorbing layer 4. The blocking property against electrons from the light-absorbing layer 4 indicates a property which only allows holes generated in the light-absorbing layer 4 to pass and which inhibits electrons from passing. A material having the property as described above is a material having a Fermi level higher than the energy level at the upper part of the conduction band of the light-absorbing layer 4. As a particular material, gold or a carbon material, such as a graphene, may be mentioned.

### <Sealing Body 6>

The sealing body 6 hardly allows water vapor to pass therethrough. The water vapor permeability of the sealing body 6 may be, for example, 1,000 cm³ (STP)·cm/(cm²·sec·cmHg×10⁹) or less. The water vapor permeability of the sealing body 6 may also be 100 cm³ (STP)·cm/(cm²·sec·cmHg×10⁹) or less. In addition, cm³ (STP) indicates the volume based on the standard condition. The sealing body 6 may completely inhibit water vapor from passing therethrough. In addition, the sealing body 6 has translucency.

As the sealing body 6, for example, a laminate film in which a thin film of a metal, an oxide, or the like is formed on a transparent resin film may be used. By the structure as described above, characteristics which hardly allow water vapor to pass can be obtained while the translucency is maintained. The laminate film may also have a thermoplastic property.

As a particular example of a material of the transparent film, a resin material may be mentioned. In more particular, for example, there may be mentioned a polyethylene, a polystyrene, a polyvinyl chloride), or a butylene rubber. As a material forming the thin film on the transparent film, for example, there may be mentioned an oxide, such as aluminum oxide or silicon dioxide, a carbide, such as silicon carbide, or a metal, such as aluminum, copper, or titanium.

A sealing method is, for example, as described below. First, the first electrode 2 and the second electrode 5 are connected to the first wire 7 and the second wire 8, respectively, by a silver paste, solder, or the like. The first wire 7 and the second wire 8 each may be formed using a copper wire. In the state described above, a laminate formed by laminating the substrate 1 to the second electrode 5 is sandwiched by laminate films. In the state in which the first wire 7 and the second wire 8 are extended outside of the laminate films, the films are adhered to each other by heat application. As a result, the sealing body 6 can be formed.

In the space sealed by the sealing body 6, a gas is contained. This gas contains, on a volume fraction basis, 5% or more of oxygen and 300 ppm or less of water. The gas may also primarily contain an inert gas. In this case, “primarily” indicates 50% or more on a volume fraction basis. Since the gas in the space sealed by the sealing body 6 contains a large amount of an inert gas, for example, the oxidation and reduction reactions represented by the formulas (1) to (3) are not likely to occur in the solar cell 100. Hence, the solar cell 100 can be stably used. As a particular example of the inert gas, for example, nitrogen or a rare gas may be mentioned. As a particular example of the rare gas, for example, argon and helium may be mentioned. The gas in the space sealed by the sealing body 6 may contain 10% or more of oxygen on a volume fraction basis and may also contain 15% or more. The oxygen concentration in the space sealed by the sealing body 6 may also be 100%. In addition, the gas in the space sealed by the sealing body 6 may contain 130 ppm or less of water and may also contain 30 ppm or less. The gas in the space sealed by the sealing body 6 may contain no water. The gas contained in the space sealed by the sealing body 6 is, for example, dried air.

As a method for controlling the composition of the gas contained in the space sealed by the sealing body 6, for example, there may be mentioned a method in which the solar cell 100 is sealed in an atmosphere having a targeted composition, a method in which when the solar cell 100 is sealed, a gas is enclosed therein, or a method in which after the solar cell 100 is sealed, a hole is formed in the sealing body 6, a gas is then enclosed through the hole, and the hole is again sealed.

### Second Embodiment

A solar cell 101 according to this embodiment is different from the solar cell 100 according to the first embodiment in terms of the structure of the sealing body.

Hereinafter, the solar cell 101 will be described. Constituent elements having the same function and the same structure as those described in the solar cell 100 will be designated by the same reference numeral as described above, and the description thereof will be omitted.

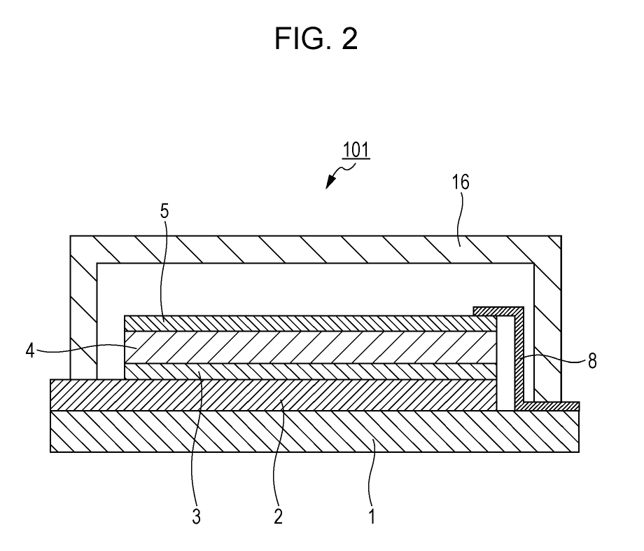

The solar cell 101 according to this embodiment includes, as shown in FIG. 2, a substrate 1, a first electrode 2, an electron transport layer 3, a light-absorbing layer 4, a second electrode 5, and a sealing body 16.

The sealing body 16 is located on the substrate 1. The sealing body 16 seals the electron transport layer 3, the light-absorbing layer 4, the second electrode 5, and a part of the first electrode 2.

Next, fundamental operation and effect of the solar cell 101 of this embodiment will be described. The function of the solar cell 101 is similar to that of the solar cell 100.

In addition, since the sealing body 16 is provided on the substrate 1, compared to the solar cell 100, the solar cell 101 can be formed to have a further space-saving structure.

The solar cell 101 of this embodiment can be formed, for example, by the following method. A procedure from the start to a step of forming the second electrode 5 in the manufacturing method of the solar cell 101 is the same as that of the manufacturing method of the solar cell 100, and hence the description thereof will be omitted. After the second electrode 5 is formed, a second wire 8 is connected to the second electrode 5. Finally, in the state in which the first electrode 2 and the second wire 8 are each partially extended to the outside, the sealing body 16 is formed so as to seal the remaining first electrode 2, the electron transport layer 3, the light-absorbing layer 4, and the second electrode 5, and as a result, the solar cell 101 can be obtained.

Hereinafter, the constituent element of the solar cell 101 will be described in detail.

### <Sealing Body 16>

The sealing body 16 hardly allows water vapor to pass therethrough. The water vapor permeability of the sealing body 16 may be, for example, 1,000 cm³ (STP)·cm/(cm²·sec·cmHg×10⁹) or less. The water vapor permeability of the sealing body 16 may also be 100 cm³ (STP)·cm/(cm²·sec·cmHg×10⁹) or less. The sealing body 16 may completely inhibit water vapor from passing therethrough. In addition, the sealing body 16 has translucency.

As the sealing body 16, for example, a glass or a resin formed to have a box shape may be used.

A sealing method is, for example, as described below. First, the second wire 8 is connected to the second electrode 5. In the state described above, the sealing body 16 is provided to cover the laminate formed from the substrate 1 to the second electrode 5 so that the first electrode 2 and the second wire 8 are partially extended to the outside of the sealing body 16. An adhesion method between the substrate 1 and the sealing body 16 is as described below. For example, a low melting point glass is applied to an edge portion of the sealing body 16 in advance. After the sealing body 16 is provided to cover the above laminate, the portion to which the low melting point glass is adhered is melted, so that the sealing body 16 and the substrate 1 can be integrated together. Alternatively, by a UV curable resin, the sealing body 16 and the substrate 1 can also be integrated together. In this case, after a UV curable resin is applied to the edge portion of the sealing body 16, the sealing body 16 is provided to cover the laminate, and UV rays are then irradiated thereon.

In addition, as is the first embodiment, the structure in which a first wire 7 is connected to the first electrode 2 may also be formed.

The composition of a gas in a space sealed by the sealing body 16 is similar to the composition of the gas sealed by the sealing body 6.

### Third Embodiment

In a solar cell 200 according to this embodiment, a moisture absorber is provided in a space sealed by a sealing body, and this is a different point from the solar cell 100 according to the first embodiment.

Hereinafter, the solar cell 200 will be described. Constituent elements having the same function and the same structure as those described in the solar cell 100 will be designated by the same reference numeral as described above, and the description thereof will be omitted.

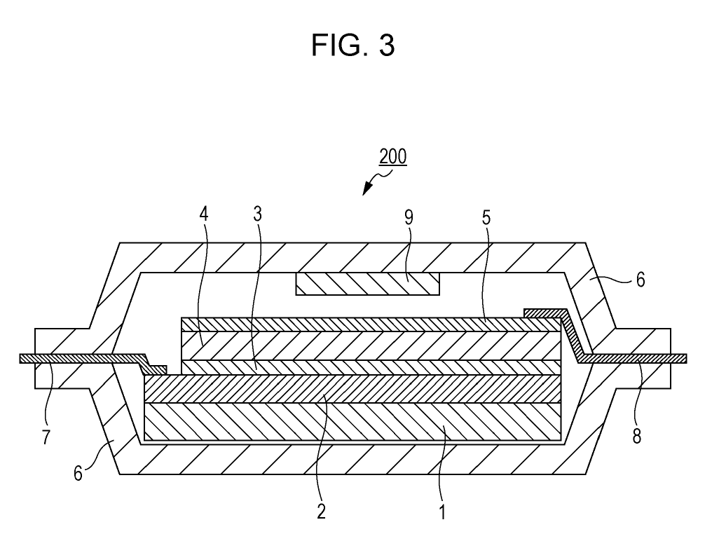

The solar cell 200 according to this embodiment includes, as shown in FIG. 3, a first electrode 2, an electron transport layer 3, a light-absorbing layer 4, a second electrode 5, and a sealing body 6.

In a space sealed by the sealing body 6, a moisture absorber 9 is located. In this embodiment, the moisture absorber 9 is disposed on the surface of the sealing body 6 facing the second electrode 5. In addition, in the space sealed by the sealing body 6, a gas is present. The gas in the space sealed by the sealing body 6 primarily contains an inert gas and 5% or more of oxygen on a volume fraction basis.

The solar cell 200 may further include a substrate 1. In this case, as shown in FIG. 3, the first electrode 2 is disposed on the substrate 1.

Next, fundamental operation and effect of the solar cell 200 of this embodiment will be described. The function of the solar cell 200 is similar to that of the solar cell 100.

In addition, since the moisture absorber 9 is provided in the space sealed by the sealing body 6, the moisture amount in the space sealed by the sealing body 6 can be reduced. Hence, as is the solar cell 100, since the decrease in conversion efficiency of the solar cell 200 with the time can be suppressed, the durability of the solar cell 200 can be improved.

The solar cell 200 may be formed by a method similar to that of the solar cell 100. The moisture absorber 9 may be provided, for example, on the rear side of the laminate film forming the sealing body 6 or on the second electrode 5.

Hereinafter, the constituent element of the solar cell 200 will be described in detail.

### <Moisture Absorber 9>

The moisture absorber 9 absorbs moisture in the space sealed by the sealing body 6. The moisture absorber 9 is, for example, a seal holding a powder which absorbs moisture. As the powder which absorbs moisture, for example, a powder of a metal element, a metal oxide, or a metal carbonate may be mentioned. As the metal, for example, an alkali metal or an alkaline earth metal may be mentioned. As concrete examples of the alkali metal, sodium and potassium may be mentioned. As concrete examples of the alkaline earth metal, calcium and magnesium may be mentioned.

### Fourth Embodiment

A solar cell 300 according to this embodiment further includes a hole transport layer, and this is a different point from the solar cell 100 according to the first embodiment.

Hereinafter, the solar cell 300 will be described. Constituent elements having the same function and the same structure as those described in the solar cell 100 will be designated by the same reference numeral as described above, and the description thereof will be omitted.

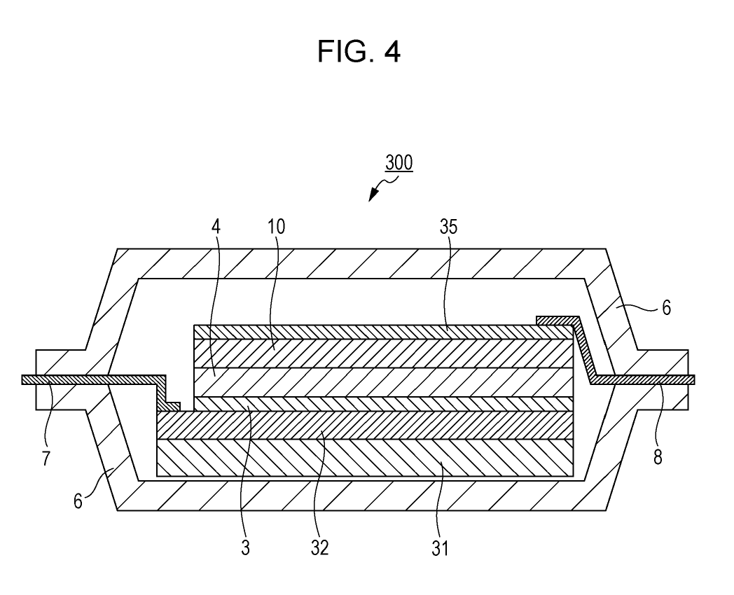

The solar cell 300 according to this embodiment includes, as shown in FIG. 4, a first electrode 32, an electron transport layer 3, a light-absorbing layer 4, a hole transport layer 10, a second electrode 35, and a sealing body 6.

The hole transport layer 10 is provided between the light-absorbing layer 4 and the second electrode 35. The sealing body 6 seals the first electrode 32, the electron transport layer 3, the light-absorbing layer 4, the hole transport layer 10, and the second electrode 35.

The solar cell 300 may further include a substrate 31. In this case, as shown in FIG. 4, the first electrode 32 is disposed on the substrate 31.

Next, fundamental operation and effect of the solar cell 300 will be described.

Since the light-absorbing layer 4 absorbs light when light is irradiated on the solar cell 300, excited electrons and holes are generated. The excited electrons move to the electron transport layer 3. On the other hand, the holes generated in the light-absorbing layer 4 move to the hole transport layer 10. The electron transport layer 3 is connected to the first electrode 32, the hole transport layer 10 is connected to the second electrode 35, and the first electrode 32 and the second electrode 35 are each electrically connected to the outside of the sealing body 6. Hence, a current can be extracted from the solar cell 300 using the first electrode 32 and the second electrode 35 as a negative electrode and a positive electrode, respectively.

In this embodiment, an effect similar to that of the first embodiment can also be obtained.

In addition, in this embodiment, the hole transport layer 10 is provided. Hence, the second electrode 35 is not required to have a blocking property against electrons from the light-absorbing layer 4. Accordingly, the range of material selection for the second electrode 35 can be increased.

In addition, the solar cell 300 includes the sealing body 6. A gas present in a space sealed by the sealing body 6 contains 5% or more of oxygen on a volume fraction basis, and the concentration of water in this gas is 300 ppm or less on a volume fraction basis. Hence, the solar cell 300 has high durability. The reason for this can be explained as follows.

In the hole transport layer 10 of the solar cell 300, by the addition of an oxidizing agent, an oxidant and a reductant of a hole transport material are simultaneously present. Since the oxidant of the hole transport material is present, the hole transport performance of the hole transport layer 10 is improved. The energy level of the valence band of the hole transport material is higher than the oxidation-reduction potential of water.

Hence, when water is present, in the hole transport layer 10, the following oxidation reaction of water occurs, and oxygen, protons, and electrons are generated.

2H₂O→O₂+4H⁺+4e⁻ (1)

For example, when the hole transport material is Spiro-OMeTAD, by the electrons generated by this reaction, the following reaction occurs.

Spiro-OMeTAD⁺e⁻→Spiro-OMeTAD (4)

As a result of the reactions represented by the formulas (1) and (4), the oxidant of the hole transport material is reduced. Hence, the hole transport performance of the hole transport layer 10 is degraded.

According to the formula (1) and be Chatelier's principle, as the amount of water around the hole transport layer 10 is increased, or the amount of oxygen is decreased, the reaction represented by the formula (1) is liable to occur. In the gas contained in the space sealed by the sealing body 6, 5% or more of oxygen on a volume fraction basis is contained, and the concentration of water is 300 ppm or less on a volume fraction basis. Hence, the probability of the occurrence of the reaction represented by the formula (1) in the solar cell 300 can be reduced. Accordingly, in the solar cell 300, the oxidant of the hole transport material contained in the hole transport layer 10 can be suppressed from being reduced. Hence, since the decrease in conversion efficiency of the solar cell 300 with the time can be suppressed, the durability thereof can be improved.

Hereinafter, the individual constituent elements of the solar cell 300 will be described in detail. In addition, the same elements as those described in the solar cell 100 will be omitted.

### <First Electrode 32 and Second Electrode 35>

Since the hole transport layer 10 is used in this embodiment, the second electrode 35 is not required to have a blocking property against electrons from the light-absorbing layer 4. That is, the second electrode 35 may be formed from a material which is in ohmic-contact with the light-absorbing layer 4. Hence, the second electrode 35 may also be formed to have translucency.

At least one of the first electrode 32 and the second electrode 35 has translucency and may be formed similar to the first electrode 2 of the first embodiment. One of the first electrode 32 and the second electrode 35 may have no translucency. In this case, a region in which no electrode material is present is not required to be formed in the electrode having no translucency.

### <Substrate 31>

The substrate 31 may be formed to have the structure similar to that of the substrate 1 of the first embodiment. In addition, when the second electrode 35 has translucency, the substrate 31 may be formed using an opaque material. For example, a metal, a ceramic, or a resin material having a low transmittance may be used as a material for the substrate 31.

### <Hole Transport Layer 10>

The hole transport layer 10 is formed, for example, of an organic material or an inorganic semiconductor. The hole transport layer 10 may be formed by laminating the same constituent material or by alternately laminating different materials.

As the organic material, for example, a phenylamine, a triphenylamine derivative having a tertiary amine skeleton, or a PEDOT compound having a thiophene structure may be mentioned. Although the molecular weight is not particularly limited, a high molecular weight material may also be used. When the hole transport layer 10 is formed using an organic material, the thickness of the hole transport layer 10 may be 1 to 1,000 nm or may also be 100 to 500 nm. When the thickness of the hole transport layer 10 is in the range described above, a sufficient hole transport performance can be obtained. In addition, when the thickness of the hole transport layer 10 is in the range described above, since a low resistance can be maintained, light power generation can be performed at a high efficiency.

As the inorganic semiconductor, a p-type semiconductor, such as CuO, Cu₂O, CuSCN, molybdenum oxide, or nickel oxide, may be used. When the hole transport layer 10 is formed using an inorganic semiconductor, the thickness of the hole transport layer 10 may be 1 to 1,000 nm or may also be 10 to 50 nm. When the thickness of the hole transport layer 10 is in the range described above, a sufficient hole transport performance can be obtained. In addition, when the thickness of the hole transport layer 10 is in the range described above, since a low resistance can be maintained, light power generation can be performed at a high efficiency.

As a method for forming the hole transport layer 10, a coating method or a printing method may be used. As the coating method, for example, there may be used a doctor blade method, a bar coating method, a spray method, a dip coating method, or a spin coating method. As the printing method, for example, a screen printing method may be mentioned. In addition, if needed, after the hole transport layer 10 is formed by mixing a plurality of materials, pressure application or firing may be performed. When the material of the hole transport layer 10 is an organic material having a low molecular weight or an inorganic semiconductor, a vacuum deposition method may also be used for the formation thereof.

The hole transport layer 10 may also contain a supporting electrolyte and a solvent.

As the supporting electrolyte, for example, an ammonium salt or an alkali metal salt may be mentioned. As the ammonium salt, for example, tetrabutylammonium perchlorate, tetraethylammonium hexafluorophosphate, an imidazolium salt, or a pyridinium salt may be mentioned. As the alkali metal salt, for example, lithium perchlorate or potassium tetrafluoroborate may be mentioned.

The solvent contained in the hole transport layer 10 may be a solvent having excellent ion conductivity. As the solvent contained in the hole transport layer 10, either an aqueous solvent or an organic solvent may be used. As the solvent contained in the hole transport layer 10, when an organic solvent is used, the solute can be further stabilized. As a particular example, a hetero cyclic-compound solvent, such as tert-butylpyridine, pyridine, or n-methylpyrrolidone may be mentioned.

In addition, as the solvent, an ionic liquid may also be used alone or may be used in combination with another type of solvent. The ionic liquid has advantages, such as a low volatility and a high fire retardancy.

As the ionic liquid, for example, an imidazolium-based ion liquid, such as 1-ethyl-3-methylimidazolium tetracyanoborate, or a pyridine-based, an alicyclic amine-based, an aliphatic amine-based, or an azonium amine-based ion liquid may be mentioned.

Those supporting electrolytes and solvents have an effect of stabilizing holes in the hole transport layer 10.

### Fifth Embodiment

A solar cell 400 according to this embodiment further includes a porous layer 11, and this is a different point from the solar cell 100 according to the first embodiment.

Hereinafter, the solar cell 400 will be described, Constituent elements having the same function and the same structure as those described in the solar cell 100 will be designated by the same reference numeral as described above, and the description thereof will be omitted.

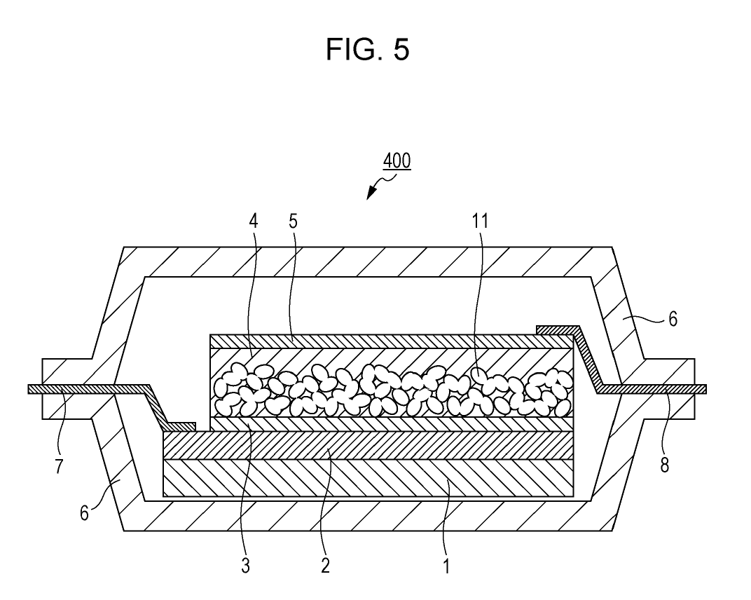

The solar cell 400 according to this embodiment includes, as shown in FIG. 5, a first electrode 2, an electron transport layer 3, the porous layer 11, a light-absorbing layer 4, a second electrode 5, and a sealing body 6.

The porous layer 11 is disposed in the light-absorbing layer 4 at a position in contact with the electron transport layer 3. The porous layer 11 contains a porous material.

Pores in the porous layer 11 are connected to each other from the upper end to the lower end of the porous layer 11 which is in contact with the electron transport layer 3. Accordingly, the material of the light-absorbing layer 4 fills the pores of the porous layer 11 and is able to reach the surface of the electron transport layer 3, Hence, since the light-absorbing layer 4 and the electron transport layer 3 are in contact with each other, electrons can be directly given and received therebetween.

The solar cell 400 may further include a substrate 1. In this case, as shown in FIG. 5, the first electrode 2 is disposed on the substrate 1.

Next, fundamental operation and effect of the solar cell 400 of this embodiment will be described. The function of the solar cell 400 is similar to that of the solar cell 100. In this embodiment, an effect similar to that of the first embodiment can be obtained.

In addition, since the porous layer 11 is provided on the electron transport layer 3, an effect in which the light-absorbing layer 4 can be easily formed on the porous layer 11 is obtained. Since the material of the light-absorbing layer 4 intrudes into the pores of the porous layer 11, the porous layer 11 functions as a basement of the light-absorbing layer 4. Hence, the material of the light-absorbing layer 4 is not likely to be repelled or aggregated on the surface of the porous layer 11. As a result, the light-absorbing layer 4 can be formed as a uniform film.

The solar cell 400 of this embodiment can be formed by a method similar to that of the solar cell 100. The porous layer 11 is formed on the electron transport layer 3 by a coating method or the like.

Hereinafter, the constituent element of the solar cell 400 will be described in detail.

### <Porous Layer 11>

The porous layer 11 functions as the basement when the light-absorbing layer 4 is formed. The porous layer 11 does not disturb the light absorption of the light-absorbing layer 4 and the electron transfer from the light-absorbing layer 4 to the electron transport layer 3.

The porous layer 11 contains a porous material. As the porous material, for example, a porous material in which insulating or semiconductor particles are connected to each other maybe mentioned. As the insulating particles, particles of aluminum oxide, silicon oxide, or the like may be used. As the semiconductor particles, for example, inorganic semiconductor particles may be used. As the inorganic semiconductor, an oxide of a metal element, a perovskite oxide, a sulfide, or a metal chalcogenide may be used. As an example the of the oxide of a metal element, an oxide of Cd, Zn, In, Pb, Mo, W, Sb, Bi, Cu, Hg, Ti, Ag, Mn, Fe, V, Sn, Zr, Sr, Ga, Si, or Cr may be mentioned. As a more particular example of the oxide of a metal element, TiO₂ may be mentioned. As an example of the perovskite oxide, SrTiO₃ or CaTiO₃ may be mentioned. As an example of the sulfide, CdS, ZnS, In₂S₃, PbS, MO₂S, WS₂, Sb₂S₃, Bi₂S₃, ZnCdS₂, or Cu₂S may be mentioned. As an example of the metal chalcogenide, CdSe, In₂Se₃, WSe₂, HgS, PbSe, or CdTe may be mentioned.

The thickness of the porous layer 11 may be 0.01 to 10 μm or may also be 0.1 to 1 In addition, the surface roughness factor of the porous layer 11 maybe 10 or more or may also be 100 or more. The surface roughness factor of an object is obtained by dividing an effective area of the object by a projected area thereof. In addition, the projected area indicates an area of a shadow formed behind the object when light is irradiated on the right front surface of the object. The effective area indicates an actual surface area of the object. The effective area can be obtained by calculation using the volume obtained from the projected area and the thickness of the object, the specific surface area of a material forming the object, and the bulk density of the material.

### Sixth Embodiment

A solar cell 500 according to this embodiment further includes a porous layer, and this is a different point from the solar cell 300 according to the fourth embodiment. In addition, the solar cell 500 further includes a hole transport layer, and this is a different point from the solar cell 400 according to the fifth embodiment.

Hereinafter, the solar cell 500 will be described. Constituent elements having the same function and the same structure as those described in the solar cells 300 and 400 will be designated by the same reference numeral as described above, and the description thereof will be omitted.

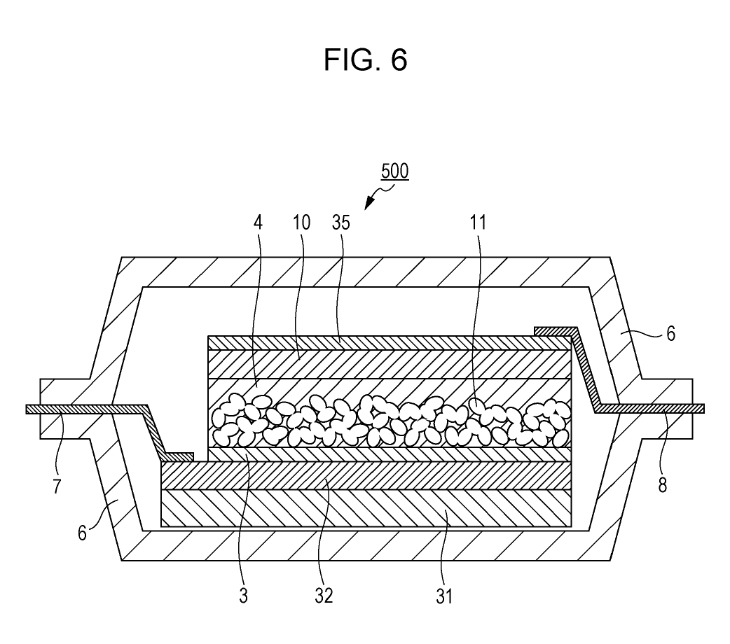

The solar cell 500 according to this embodiment includes, as shown in FIG. 6, a first electrode 32, an electron transport layer 3, a porous layer 11, a light-absorbing layer 4, a hole transport layer 10, a second electrode 35, and a sealing body 6.

The solar cell 500 may further include a substrate 31. In this case, as shown in FIG. 6, the first electrode 32 is disposed on the substrate 31.

Next, fundamental operation and effect of the solar cell 500 of this embodiment will be described. The functions of the solar cell 500 are similar to those of the solar cells 300 and 400. In this embodiment, effects similar to those of the third and the fourth embodiments can be obtained.

The solar cell 500 of this embodiment may be formed by methods similar to those of the solar cells 300 and 400.

In addition, the solar cell according to the third embodiment may have the structure in which in the solar cell of the second embodiment, the moisture absorber 9 is provided. The solar cell according to the fourth embodiment may have the structure in which in the solar cell of the second embodiment, the hole transport layer 10 is provided. The solar cell according to the fifth embodiment may have the structure in which in the solar cell of the second embodiment, the porous layer 11 is provided. The solar cell according to the sixth embodiment may have the structure in which in the solar cell of the second embodiment, the hole transport layer 10 and the porous layer 11 are provided. In those cases described above, an effect similar to that of the solar cell according to the second embodiment may also be obtained. In addition, from the fourth embodiment to the sixth embodiment, in the space sealed by the sealing body 6, the moisture absorber 9 may also be provided. When the moisture absorber 9 is provided, the concentration of water in the space sealed by the sealing body 6 can be easily maintained at 300 ppm or less on a volume fraction basis. Hence, the light-absorbing material and the hole transport material can be further suppressed from being decomposed.

### EXAMPLES

Hereinafter, the present disclosure will be described in detail with reference to examples, After solar cells of Examples 1 to 8 and Comparative Examples 1 to 5 were formed, the characteristics thereof were evaluated. The evaluation results are collectively shown in Table 1.

### Example 1

As shown in FIG. 6, a solar cell having the same structure as that of the solar cell 500 was formed. Individual constituent elements thereof were as described below.
Substrate 31: glass substrate (thickness: 1 mm)
First electrode 32: fluorine-doped SnO₂ layer (surface resistance: 10 Ω/sq.)
Electron transport layer 3: titanium oxide (thickness: 30 nm)
Porous layer 11: porous titanium oxide
Light-absorbing layer 4: CH₃NH₃PbI₃
Hole transport layer 10: Spiro-OMeTAD (manufactured by Merck)
Second electrode 35: gold (thickness: 80 nm)
Sealing body 6: laminate film (PTS bag PB180250P, manufactured by Mitsubishi Gas Chemical Company, Inc.)
First wire 7, second wire 8: copper wire

The solar cell of Example 1 was formed as described below.

As the substrate 31, a glass substrate (manufactured by Nippon Sheet Glass Company, Limited) having a thickness of 1 mm was used. On the substrate 31, a fluorine-doped SnO₂ layer functioning as the first electrode 32 was disposed.

On the first electrode 32, as the electron transport layer 3, a titanium oxide layer having a thickness of approximately 30 nm was formed by a sputtering method.

Next, a highly pure titanium oxide powder having an average primary particle diameter of 20 nm was dispersed in an ethyl cellulose, so that a titanium oxide paste for screen printing was formed. The titanium oxide paste was applied on the electron transport layer 3 and was then dried. Furthermore, firing was performed at 500° C. for 30 minutes in the air, so that a porous layer 11 having a thickness of 0.2 μm was formed as a porous titanium oxide layer.

Next, a dimethyl sulfoxide (DMSO) solution containing PbI₂ and CH₃NH₃I each having a concentration of 3 mol/L was prepared. In addition, this solution was applied on the porous layer 11 by spin coating. Subsequently, the substrate 31 was heat-treated at 130° C. on a hot plate, so that a CH₃NH₃PbI₃ layer having a perovskite structure was formed as the light-absorbing layer 4. The thickness of the light-absorbing layer 4 was 300 nm.

A chlorobenzene solution containing 60 mmol/L of Spiro-OMeTAD, 30 mmol/L of lithium bis(trifluorosulfonyl)imide (LiTFSI), 200 mmol/L of tert-butylpyridine (tBP), and 1.2 mmol/L of a Co complex (FK209, manufactured by Dyesol) was prepared and then applied on the light-absorbing layer 4 by spin coating, so that the hole transport layer 10 was formed. The thickness of the hole transport layer 10 was 100 nm. Next, on the hole transport layer 10, gold was deposited to have a thickness of 80 nm, so that the second electrode 35 was formed.

The following steps were performed in a glove box. In the glove box, the dew point was set to −60° C., and the air was allowed to flow at a flow rate of 200 ml/min. In this example, the air was formed by mixing 20% of an oxygen gas and 80% of a nitrogen gas on a volume basis. On the second electrode 35, a moisture absorber containing calcium carbonate was disposed. In addition, the first wire 7 and the second wire 8 were connected to the first electrode 32 and the second electrode 35, respectively. The laminate films were placed from the top and the bottom to cover the layers described above and to sandwich the first wire 7 and the second wire 8. The edges of the laminate films were melted by heating at 200° C. for sealing, so that the sealing body 6 was formed.

### Examples 2 to 6 and Comparative Examples 1 to 4

In the solar cell of Example 1, the moisture concentration and the oxygen concentration in the space sealed by the sealing body 6 were changed by adjusting the dew point and the air flow rate in the glove box as shown in Table 1, so that the solar cells of Examples 2 to 6 and Comparative Examples 1 to 4 were formed. In addition, as for Examples 3 to 6 and Comparative Examples 2 and 4, a nitrogen gas was allowed to flow in the glove box at the flow rate shown in Table 1. [Examples 7 and 8 and Comparative Example 5]

Except that among the individual constituent elements of the solar cell, the light-absorbing layer 4 was formed of a perovskite type compound represented by (CH(NH₂)₂)_{0.85}(CH₃NH₃)_{0.15}Pb(I_{0.85}Br_{0.15})₃, the solar cells of Examples 7 and 8 and Comparative Example 5 each having the same structure as that of Example 1 were formed.

The light-absorbing layer 4 of each of the solar cells of Examples 7 and 8 and Comparative Example 5 was formed as described below. The steps other than the step of forming the light-absorbing layer 4 were similar to those described in Example 1, so that the description thereof was omitted.

A dimethyl sulfoxide (DMSO) solution containing PbBr₂, CH₃NH₃Br, PbI₂, and CH(NH₂)₂I at concentrations of 0.45, 0.45, 2.55, and 2.55 mol/L, respectively, was prepared. In addition, this solution was applied on the porous layer 11 by spin coating. Subsequently, the substrate 31 was heat-treated at 130° C. on a hot plate, so that a (CH(NH₂)₂)_{0.85}(CH₃NH₃)_{0.15}Pb(I_{0.85}Br_{0.15})₃ layer having a perovskite structure was formed as the light-absorbing layer 4. The thickness of the light-absorbing layer 4 was 500 nm.

The sealing body 6 was formed by a step similar to that of Example 1, so that the solar cell of Example 7 was formed. Except that in the glove box, the air and the oxygen gas were allowed to flow at flow rates of 180 and 20 ml/min, respectively, the sealing body 6 was formed by a step similar to that of Example 1, so that the solar cell of Example 8 was formed. Except that in the glove box, a nitrogen gas was allowed to flow at a flow rate 200 ml/min instead of using the air, the sealing body 6 was formed by a step similar to that of Example 1, so that the solar cell of Comparative Example 5 was formed.

### <Characteristics Evaluation>

### [Composition Analysis of Gas]

The moisture concentration in the gas in the space sealed by the sealing body 6 was measured by the following method. In Examples 1 and 6 and Comparative Example 2, an API-MS measurement was performed. In Example 2 and Comparative Examples 1 and 4, measurement was performed using a Karl Fischer measurement apparatus. In Examples 3 to 5, 7, and 8 and Comparative Examples 3 and 5, the moisture concentration was calculated using the dew point, the air flow rate, the nitrogen flow rate, and the oxygen flow rate in the glove box during manufacturing of the solar cell.

The oxygen concentration in the gas in the space sealed by the sealing body 6 was calculated using the dew point, the air flow rate, the nitrogen flow rate, and the oxygen flow rate in the glove box during manufacturing of the solar cell. In addition, in the gas in the space sealed by the sealing body 6, besides oxygen and water, nitrogen was also contained. In addition, the moisture concentration and the oxygen concentration shown in Table 1 are each represented by a volume fraction.

### [Measurement of Conversion Efficiency]

By the use of a solar simulator, light having a illuminance of 100 mW/cm² was irradiated on each solar cell. The current-voltage characteristic of each solar cell was measured, and the conversion efficiency was obtained after stabilization as an initial conversion efficiency. In addition, after the initial conversion efficiency was measured, each solar cell was stored in a constant-temperature bath set at a temperature of 85° C., and a heating test was performed for 72 hours. After the heating test was completed, the conversion efficiency of each solar cell was obtained by measurement of the current-voltage characteristic. The rate of the conversion efficiency after the heating test (post-test conversion efficiency) to the initial conversion efficiency was calculated as the retention rate of each solar cell.

TABLE 1

| | In Glove Box | | | | In Space Sealed By Sealing | | | | |
|---|---|---|---|---|---|---|---|---|---|
| | | | Nitrogen | Oxygen | Body | | Initial | Post-Test | |
| | Dew | Air How | Flow | Flow | Moisture | Oxygen | Conversion | Conversion | Retention |
| | Point | Rate | Rate | Rate | Concentration | Concentration | Efficiency | Efficiency | Rate |
| | (° C.) | (ml/min.) | (ml/min.) | (ml/min.) | (ppm) | (%) | (%) | (%) | (%) |
| Example 1 | −60 | 200 | — | — | 3.6 | 20 | 10.1 | 10.0 | 99 |
| Example 2 | −40 | 200 | — | — | 130 | 20 | 11.2 | 10.9 | 97 |
| Example 3 | −60 | 60 | 180 | — | 2.6 | 5 | 12.9 | 10.5 | 82 |
| Example 4 | −64 | 100 | 100 | — | 3.0 | 10 | 11.8 | 11.2 | 95 |
| Example 5 | −66 | 150 | 50 | — | 3.6 | 15 | 12.3 | 12.9 | 105 |
| Example 6 | −66 | 180 | 20 | — | 3.9 | 28 | 8.2 | 7.8 | 95 |
| Example 7 | −60 | 200 | — | — | 3.6 | 20 | 7.8 | 7.8 | 100 |
| Example 8 | −60 | 180 | — | 20 | 3.3 | 28 | 8.7 | 8.8 | 101 |
| Comparative | −30 | 200 | — | — | 380 | 20 | 9.9 | 6.1 | 62 |
| Example 1 | | | | | | | | | |
| Comparative | −53 | 30 | 170 | — | 4.2 | 3 | 9.5 | 3.5 | 37 |
| Example 2 | | | | | | | | | |
| Comparative | +5 | 200 | — | — | 8600 | 20 | 10.3 | 0.3 | 3 |
| Example 3 | | | | | | | | | |
| Comparative | −20 | 30 | 170 | — | 380 | 2 | 10.9 | 4.9 | 45 |
| Example 4 | | | | | | | | | |
| Comparative | — | — | 200 | — | 1 | 0 | 9.7 | 5.0 | 52 |
| Example 5 | | | | | | | | | |

From the results shown in Table 1, in the solar cells of Examples 1 to 8, even after the heating test is performed, a retention rate of 82% or more is obtained. On the other hand, in the solar cells of Comparative Examples 1 to 5, the retention rate is only 62% or less.

For example, Examples 1 and 2 are compared to Comparative Examples 1 and 3, in each of which the light-absorbing layer 4 is formed from a perovskite type compound represented by CH₃NH₃PbI₃, and the oxygen concentration is 20%. In Examples 1 and 2 in which the moisture concentration is 130 ppm or less, the retention rate is high, such as 97% or more. On the other hand, in Comparative Example 1 in which the moisture concentration is 380 ppm, the retention rate is decreased to 62%, and in Comparative Example 3 in which the moisture concentration is 8,600 ppm, the retention rate is seriously decreased to 3%. From the results described above, it is found that when the oxygen concentration in the solar cell is sufficiently high, by decreasing the moisture concentration in the space sealed by the sealing body, the durability of the solar cell can be improved.

In addition, Examples 1 and 3 to 5 are compared to Comparative Example 2, in each of which the light-absorbing layer 4 is formed from a perovskite type compound represented by CH₃NH₃PbI₃ and the moisture concentration is 2 to 5 ppm. In Example 3 in which the oxygen concentration is 5%, a retention rate of 82% can be obtained, and in Examples 1, 4, and 5 in each of which the oxygen concentration is 10% or more, a retention rate of 95% or more can be obtained. On the other hand, in Comparative Example 2 in which the oxygen concentration is 3%, the retention rate is decreased to 37%. From the results described above, it is found that when the moisture concentration is sufficiently low, by increasing the oxygen concentration, the durability of the solar cell can be improved.

In addition, from the results obtained in Examples 7 and 8 and Comparative Example 5, it is found that in the case in which the light-absorbing layer 4 is formed from a perovskite type compound represented by (CH(NH₂)₂)_{0.85}(CH₃NH₃)_{0.15}Pb(I_{0.85}Br_{0.15})₃, when the moisture concentration is sufficiently low, by increasing the oxygen concentration, the durability of the solar cell can also be improved.

From the results described above, when the sealing body is included in the solar cell, 5% or more of oxygen on a volume fraction basis is contained in the gas in the space sealed by the sealing body 6, and the concentration of water in the gas is set to 300 ppm or less on a volume fraction basis, the durability of the solar cell can be improved.

What is claimed is:

1. A solar cell comprising:
a first electrode;
an electron transport layer which is located on the first electrode and which contains a semiconductor;
a light-absorbing layer which is located on the electron transport layer and which contains a perovskite type compound represented by a composition formula AMX₃, where A is a site for one or more monovalent cations, M is a site for one or more divalent cations, and X is a site for one or more halide anions;
a second electrode which is located on the light-absorbing layer; and
a sealing body which seals at least a part of the first electrode, the electron transport layer, the light-absorbing layer, and at least a part of the second electrode, wherein:
a gas is present in a space between the sealing body and each of the at least a part of the first electrode, the electron transport layer, the light-absorbing layer, and the at least a part of the second electrode;
the gas contains oxygen;
a concentration of the oxygen in the gas is 5% or more on a volume fraction basis; and
a concentration of water in the gas is 300 ppm or less on a volume fraction basis.

2. The solar cell according to claim 1, wherein:
the gas further contains an inert gas; and
a concentration of the inert gas in the gas is 50% or more on a volume fraction basis.

3. The solar cell according to claim 1,
wherein the concentration of water in the gas is 130 ppm or less on a volume fraction basis.

4. The solar cell according to claim 1,
wherein the gas is in contact with the light-absorbing layer.

5. The solar cell according to claim 1,
further comprising a hole transport layer disposed between the light-absorbing layer and the second electrode,
wherein the sealing body further seals the hole transport layer.

6. The solar cell according to claim 5,
wherein the gas is in contact with the hole transport layer.

7. The solar cell according to claim 1,
further comprising a porous layer disposed in the light-absorbing layer, the porous layer being in contact with the electron transport layer and containing a porous material.

8. The solar cell according to claim 1,
wherein the semiconductor is titanium oxide.

9. The solar cell according to claim 1,
wherein the one or more monovalent cations include at least one selected from the group consisting of a methylammonium cation and a formamidinium cation.

10. The solar cell according to claim 1,
wherein the one or more divalent cations include at least one selected from the group consisting of Pb²⁺, Ge²⁺, and Sn²⁺.

11. A solar cell comprising:
a first electrode;
an electron transport layer which is located on the first electrode and which contains a semiconductor;
a light-absorbing layer which is located on the electron transport layer and which contains a perovskite type compound represented by a composition formula AMX₃, where A is a site for one or more monovalent cations, M is a site for one or more divalent cations, and X is a site for one or more halide anions;
a second electrode which is located on the light-absorbing layer;
a sealing body which seals at least a part of the first electrode, the electron transport layer, the light-absorbing layer; and at least a part of the second electrode; and
a moisture absorber located between the sealing body and each of the at least a part of the first electrode, the electron transport layer, the light-absorbing layer, and the at least a part of the second electrode, wherein:
a gas is present between the sealing body and each of the at least a part of the first electrode, the electron transport layer, the light-absorbing layer, and the at least a part of the second electrode;
the gas contains oxygen; and
a concentration of the oxygen in the gas is 5% or more on a volume fraction basis.

12. The solar cell according to claim 11, wherein:
the gas further contains an inert gas; and
a concentration of the inert gas in the gas is 50% or more on a volume fraction basis.

13. The solar cell according to claim 11,
wherein the gas is in contact with the light-absorbing layer.

14. The solar cell according to claim 11,
further comprising a hole transport layer disposed between the light-absorbing layer and the second electrode,
wherein the sealing body further seals the hole transport layer.

15. The solar cell according to claim 14,
wherein the gas is in contact with the hole transport layer.

16. The solar cell according to claim 11,
further comprising a porous layer disposed in the light-absorbing layer, the porous layer being in contact with the electron transport layer and containing a porous material.

17. The solar cell according to claim 11,
wherein the semiconductor is titanium oxide.

18. The solar cell according to claim 11,
wherein the one or more monovalent cations include at least one selected from the group consisting of a methylammonium cation and a formamidinium cation.

19. The solar cell according to claim 11,
wherein the one or more divalent cations include at least one selected from the group consisting of Pb²⁺, Ge²⁺, and Sn²⁺.
